(19) United States
(12) Patent Application Publication
(10) Pub. No.: US 2026/0342315 A1
(43) Pub. Date: Oct. 29, 2026

(54) ELASTIC WAVE DEVICE

(71) Applicant: TOHOKU UNIVERSITY, Sendai-shi (JP)

(72) Inventors: Michio KADOTA, Sendai-shi (JP); Shuji TANAKA, Sendai-shi (JP)

(73) Assignee: TOHOKU UNIVERSITY, Sendai-shi (JP)

(21) Appl. No.: 19/643,461

(22) Filed: Apr. 9, 2026

(30) Foreign Application Priority Data
Apr. 23, 2025 (JP) 2025-071765

(51) Int. Cl. H03H 9/64; H03H 9/02; H03H 9/145

(52) U.S. Cl. CPC H03H 9/6483; H03H 9/02559; H03H 9/02685; H03H 9/14538; H03H 9/6413

(57) ABSTRACT

[Problem] To provide an elastic wave device and a ladder filter that can cope with high frequencies required for 5G and FR3, and can obtain excellent withstand voltage and a relatively high impedance value without increasing the size of the device itself.

[Solution] A pair of comb-tooth electrodes 11a, 11b are arranged side by side on one surface of a piezoelectric substrate. A common electrode 12 electrically couples each comb-tooth electrode 11a, 11b. Each comb-tooth electrode 11a, 11b has a plurality of electrode fingers 21a, 22a arranged parallel to each other. The common electrode 12 has a plurality of common electrode fingers 23a arranged parallel between the electrode fingers 21a and between the electrode fingers 22a, and the common electrode fingers 23a are electrically connected to each other.

### FIELD OF THE INVENTION

The present invention relates to an elastic wave (surface acoustic wave) device and a ladder filter.

### DESCRIPTION OF RELATED ART

In mobile communications such as smartphones, frequencies in the 700 MHz to 3.5 GHz band are used as fourth generation (4G) frequencies, but for the purpose of countermeasures against frequency congestion and high-speed and large-capacity communication, higher frequencies in the 3.6 to 5 GHz band and the 24 to 40 GHz band have been allocated as fifth generation (5G) frequencies. Furthermore, it is planned to allocate frequency bands of 40 GHz or higher as sixth generation frequencies.

However, the millimeter wave band of 24 GHz or higher has the disadvantage of being vulnerable to obstacles such as buildings and of radio waves not reaching far distances, and therefore has the problem of being limited to use indoors, in factories, and the like. Therefore, in recent years, the 7 to 24 GHz band, which is not allocated to 5G or 6G, has been attracting attention and is defined by 3GPP (Third Generation Partnership Project) as the frequency band of FR3 (Frequency Band 3). Currently, the only filter used in this frequency band is an LC filter consisting of coils and capacitors, and the emergence of a surface acoustic wave (SAW) filter having steep characteristics and good temperature characteristics is expected.

FIG. 11(a) to 11(d) show the configuration, symbol, equivalent circuit, and frequency characteristics of a SAW resonator, respectively. In the surface acoustic wave (SAW) resonator shown in FIG. 11(a), the frequency used is determined by the velocity of the substrate divided by the period (wavelength λ) of the interdigital transducer (IDT). The velocity of a 42°YX LiTaO₃ (LT) substrate, which is a common material for SAW, is 3,800 m/s, and the wavelength λ of the IDT becomes 1.2 μm or more due to the limits of power durability and manufacturing technology, so the upper limit of frequency is in the 3 GHz band (see, for example, Non-Patent Literature 1).

Filters utilizing the characteristics of SAW resonators include the transversely coupled multimode resonator filter shown in FIG. 12(a) (see, for example, Patent Literature 1), the longitudinally coupled multimode resonator filter shown in FIG. 12(b), the T-type ladder filter shown in FIG. 12(c) in which SAW resonators are configured in a ladder shape, and the π-type ladder filter shown in FIG. 12(d). In addition, in circuit configurations using filters such as SAW filters and SAW resonators, 50 ohms is used as the reference impedance for design. This design impedance corresponds to, for example, the impedance at the center frequency between the resonance frequency (fr) and the antiresonance frequency (fa) in the frequency characteristics of the SAW resonator shown in FIG. 11(d) (indicated by a circle in the figure). The impedance in the case shown in FIG. 11(d) is 100 ohms.

FIG. 13 shows the impedance characteristics when C₀ is 4 pF, 2 pF, 1 pF, 0.5 pF, and 0.25 pF, respectively, in the equivalent circuit shown in FIG. 11(c). The curve of each impedance characteristic shown in FIG. 13 becomes the baseline of impedance outside the resonance-antiresonance frequency range of the frequency characteristics of the SAW resonator. As shown in FIG. 13, it can be seen that regardless of the value of C₀, the impedance value decreases as the frequency increases. This impedance value corresponds to the impedance value at the center frequency between fr and fa. For example, for each value of C₀, the impedance value becomes 50 ohms at 0.8 GHz, 1.6 GHz, 3.2 GHz, 6.4 GHz, and 12.8 GHz, respectively. From this, it can be seen that in order to fabricate a high-frequency resonator, it is necessary to reduce the capacitance C₀ of the resonator.

In addition, the impedance of a SAW filter also depends on the number of pairs of IDTs (the number of electrode fingers is 2×number of pairs+1) and the crossing width of the electrode fingers. However, even if the number of pairs and the aperture (crossing width) of the IDT are the same, and even if the capacitance C₀ of the IDT is the same, as shown in FIG. 13, the impedance value becomes lower as the frequency becomes higher. In order to suppress this decrease in impedance value, it is necessary to reduce the number of pairs and the aperture of the IDT, but there are limits to this countermeasure, such as weakening of the SAW excitation intensity.

In addition, duplexers used in smartphones and the like are composed of ladder filters, and when high power is applied to a duplexer, there was a problem that the IDT of the SAW resonators constituting the ladder filter would be damaged. Therefore, conventionally, as a method to increase power durability and prevent damage to the IDT, it has been necessary to set the wavelength λ of the IDT to 1.2 μm or more (see, for example, Non-Patent Literature 1).

In addition, as a method to increase the impedance value and increase the withstand voltage to prevent damage to the IDT, there is a method of connecting a plurality of SAW resonators in series in the direction perpendicular to the propagation direction of the SAW, thereby distributing the applied power to each resonator. In this case, for example, by using two SAW resonators connected in series as shown in FIG. 2(b) as each resonator of the T-type ladder filter shown in FIG. 12(c), it has been confirmed that the power applied to one SAW resonator is halved and the impedance is also doubled compared to the case of using one SAW resonator (see, for example, Non-Patent Literature 2).

The present inventors have developed a surface wave device utilizing SH-type surface waves, in which by dividing one comb-shaped electrode of an interdigital transducer (IDT) provided on a piezoelectric substrate, capacitance can be reduced and spurious responses due to higher-order modes can be effectively suppressed (see, for example, Patent Literature 2). However, this device is an edge-reflection type surface wave device in which the IDT is formed on a ceramic substrate and the electrode fingers at both ends of the IDT are limited to half the width of the other electrode fingers, and is different from a SAW resonator having grating reflectors.

### CITATION LIST

### Non-Patent Literature

Non-Patent Literature 1: T. Kimura et al., “3.5 GHz longitudinal leaky surface acoustic wave resonator using a multilayered waveguide structure for high acoustic energy confinement”, Jpn. J. Appl. Phys., 2018, 57, 07LD15, 2018.

Non-Patent Literature 2: R. Takayama et al., “Impact of composition and structure of Al alloy electrodes to power durability of SAW devices”, 2014 IEEE International Ultrasonics Symposium, p. 886

### Patent Literature

Patent Literature 1: Japanese Patent Application Laid-Open No. H10-261938
Patent Literature 2: Japanese Patent Application Laid-Open No. H5-291869

### SUMMARY OF THE INVENTION

In conventional SAW devices using general LT substrates, as shown in Non-Patent Literature 1, a wavelength λ of the IDT of 1.2 μm or more is required, so the upper limit of the frequency to be used is in the 3 GHz band, and there was a problem that it could not cope with the high frequencies required for 5G and FR3. In addition, in conventional SAW devices as described in Non-Patent Literature 1, although the withstand voltage can be increased by increasing the wavelength λ of the IDT, there was a problem that the frequency decreases and it becomes even more impossible to cope with high frequencies, and the size of the device itself also becomes larger.

In the SAW device described in Non-Patent Literature 2, by increasing the number of SAW resonators and connecting them in series, the impedance value and the withstand voltage can be increased, but there was still a problem that the size of the device itself becomes larger.

The present invention has been made with a focus on such problems, and aims to provide a surface acoustic wave (elastic wave) device and a ladder filter that can cope with the high frequencies required for 5G and FR3, and can obtain excellent withstand voltage and a relatively high impedance value without increasing the size of the device itself.

### Means for Solving the Problem

In order to achieve the above object, a surface acoustic wave (elastic wave) device according to the present invention comprises a piezoelectric substrate; a pair of comb-tooth electrodes which are arranged side by side along a propagation direction of surface acoustic waves on one surface of the piezoelectric substrate and are respectively connected to a pair of terminals for applying voltage; and a common electrode which electrically couples each comb-tooth electrode, wherein each comb-tooth electrode has a plurality of electrode fingers arranged parallel to each other at predetermined intervals along the propagation direction of surface acoustic waves, between electrode fingers of one comb-tooth electrode and between electrode fingers of the other comb-tooth electrode are arranged at intervals from each other so as not to interdigitate with each other, and the common electrode has a plurality of common electrode fingers arranged parallel to and at intervals from adjacent electrode fingers between electrode fingers of one comb-tooth electrode and between electrode fingers of the other comb-tooth electrode, and the common electrode fingers are electrically connected to each other.

In the surface acoustic wave device according to the present invention, since between electrode fingers of one comb-tooth electrode and between electrode fingers of the other comb-tooth electrode are arranged at intervals from each other so as not to interdigitate with each other, and the common electrode fingers of the common electrode are arranged between the electrode fingers of one comb-tooth electrode and between the electrode fingers of the other comb-tooth electrode, the capacitance can be reduced compared to a conventional interdigital transducer of the same size, and excellent withstand voltage and a relatively high impedance value can be obtained. The surface acoustic wave device according to the present invention can excite surface acoustic waves including boundary acoustic waves.

For example, a specific example of the surface acoustic wave device according to the present invention shown in FIG. 1 is compared with a specific example of a conventional surface acoustic wave device 50 shown in FIG. 2. First, FIG. 2(a) shows a surface acoustic wave device 50 having a conventional interdigital transducer (IDT) 52 with nine pairs of electrode fingers and a pair of reflectors 53 on a piezoelectric substrate, FIG. 2(b) shows two surface acoustic wave devices 50 shown in FIG. 2(a) connected in series (ladder-like) in the direction perpendicular to the propagation direction of the surface acoustic wave, and FIG. 2(c) shows four surface acoustic wave devices 50 shown in FIG. 2(a) connected in series in the direction perpendicular to the propagation direction of the surface acoustic wave. A and B in the figures are electrodes for applying voltage. FIG. 2(d) shows a modified structure of FIG. 2(b), in which two surface acoustic wave devices 50 shown in FIG. 2(a) are connected in series along the propagation direction of the surface acoustic wave.

When, for example, a voltage V is applied to the IDT 52 of the conventional surface acoustic wave device 50 shown in FIG. 2(a) (between terminal A and terminal B in the figure), the voltage between adjacent electrode fingers of the IDT 52 is V, and the electric field E becomes 2V/wavelength (wavelength is the wavelength of the IDT). In addition, when the same voltage V is applied between terminal A and terminal B, in the two devices connected in series in FIG. 2(b), compared to the surface acoustic wave device 50 shown in FIG. 2(a), the capacitance becomes ½ and the impedance value becomes doubled, and in one resonator of the two resonators, the voltage between each electrode finger is V/2, and the electric field E is V/wavelength. In addition, in the four devices connected in series in FIG. 2(c), compared to the surface acoustic wave device 50 shown in FIG. 2(a), the capacitance becomes ¼ and the impedance value becomes four times, and the voltage between each electrode finger is V/4, and the electric field E is V/(2 wavelengths). As is also clear from FIG. 2, FIG. 2(b), 2(c), and 2(d) provide a reflector 53 for each interdigital transducer 52, and have sizes that are twice, four times, and twice, respectively, that of the surface acoustic wave device 50 shown in FIG. 2(a). In terms of power durability, in reality, the applied voltage is more important than the power, and evaluation is made here using voltage.

On the other hand, the surface acoustic wave device according to the present invention shown in FIG. 1 has one comb-tooth electrode connected to terminal A for applying voltage and arranged along the propagation direction of the surface acoustic wave and having four electrode fingers, another comb-tooth electrode connected to terminal B for applying voltage and arranged along the propagation direction of the surface acoustic wave and having four electrode fingers, and a common electrode which is a floating electrode having ten common electrode fingers. The surface acoustic wave device according to the present invention shown in FIG. 1 corresponds to dividing the IDT 52 in FIG. 2(a) into two and connecting the resonators of the two IDTs in series, and the total number of electrode fingers, which is the sum of the number of electrode fingers of each comb-tooth electrode and the number of common electrode fingers of the common electrode, is approximately the same as the number of electrode fingers of the IDT 52 in FIG. 2(a). In the surface acoustic wave device according to the present invention shown in FIG. 1, when a voltage V is applied between one comb-tooth electrode and the other comb-tooth electrode (between electrode A and electrode B in the figure), the voltage between one comb-tooth electrode (electrode A) and the common electrode (electrode C), and between the other comb-tooth electrode (electrode B) and the common electrode (electrode C), respectively becomes V/2.

Here, in the surface acoustic wave device according to the present invention shown in FIG. 1, the portion where one comb-tooth electrode and the common electrode interdigitate, and the portion where the other comb-tooth electrode and the common electrode interdigitate, both have a number of electrode fingers that is half the number of electrode fingers of the conventional surface acoustic wave device shown in FIG. 2(a), and since two resonators composed of half the electrode fingers are connected in series, the capacitance becomes ½ of that of the conventional surface acoustic wave device shown in FIG. 2(a). In addition, since the two comb-tooth electrodes of the surface acoustic wave device according to the present invention shown in FIG. 1 are coupled in series via the common electrode, compared to the conventional surface acoustic wave device shown in FIG. 2(a), the capacitance becomes ¼ and the impedance value becomes four times. In addition, the surface acoustic wave device according to the present invention shown in FIG. 1 has excellent withstand voltage because the voltage between mutually interdigitating electrodes is halved compared to the conventional surface acoustic wave device shown in FIG. 2(a). In addition, since the capacitance and impedance value of the surface acoustic wave device according to the present invention shown in FIG. 1 are the same as those of FIG. 2(c), in which four conventional surface acoustic wave devices shown in FIG. 2(a) are connected in series, the same capacitance and impedance value can be obtained with ¼ the size.

In FIGS. 1 and 2, the surface acoustic wave device according to the present invention (see FIG. 1) when each comb-tooth electrode has approximately ½ the number and length of a conventional IDT and has four pairs of electrode fingers each with the common electrode, respectively, has been described with respect to a conventional surface acoustic wave device having an IDT with nine pairs of electrode fingers (see FIG. 2(a)), but in general, in the case of a structure in which a conventional surface acoustic wave device having N pairs of electrode fingers is divided into M pieces and M resonators are connected in series, the principle in FIG. 1 applies as is (where N and M are natural numbers of 2 or more, and N≥M). That is, in this case, the surface acoustic wave device according to the present invention has an IDT capacitance of 1/M² and an impedance value of M² times compared to the conventional surface acoustic wave device. This is considered to hold if the number of pairs of electrode fingers formed by each electrode finger of one comb-tooth electrode and each common electrode finger of the common electrode is 0.7×N/M to 1.3×N/M.

Thus, the surface acoustic wave device according to the present invention can obtain excellent withstand voltage and a relatively high impedance value without increasing the size of the device itself. In addition, since a small capacitance can be achieved with a high impedance value, it can easily cope with high frequencies (for example, 4 GHz or higher) required for 5G and FR3.

In the surface acoustic wave device according to the present invention, it is preferable that the number of electrode fingers of one comb-tooth electrode and the number of electrode fingers of the other comb-tooth electrode are approximately the same. In addition, where λ is the wavelength of each comb-tooth electrode, it is preferable that the interval between the center lines of adjacent electrode fingers among the electrode fingers of each comb-tooth electrode and the common electrode fingers of the common electrode arranged parallel to each other is λ/2. In this case, it is possible to more effectively cope with high frequencies required for 5G and FR3. In addition, each comb-tooth electrode may be electrically connected at the same-side ends of each electrode finger, or may be electrically connected at opposite-side ends. In addition, the common electrode is not electrically connected to the electrode fingers of each comb-tooth electrode, and it is sufficient if the common electrode fingers are electrically connected, and may be electrically connected to each common electrode finger only on one end side or the other end side, or may be electrically connected on one end side and the other end side.

In the surface acoustic wave device according to the present invention, as shown in FIG. 1, the common electrode may have one or more common electrode fingers arranged parallel to each electrode finger between the comb-tooth electrodes. In this case, since between electrode fingers of one comb-tooth electrode and between electrode fingers of the other comb-tooth electrode are not directly adjacent to each other, the voltage between each electrode finger can be reduced. In this case, portions of the common electrode fingers arranged between the comb-tooth electrodes may interdigitate with each other. In addition, the common electrode may also have common electrode fingers arranged parallel to each electrode finger on the side of the one comb-tooth electrode opposite to the other comb-tooth electrode and/or on the side of the other comb-tooth electrode opposite to the one comb-tooth electrode.

In the surface acoustic wave device according to the present invention, each comb-tooth electrode and the common electrode may be embedded in one surface of the piezoelectric substrate. In this case, for example, high-frequency harmonics of 4 GHz or higher can be effectively excited, and it is possible to easily cope with high frequencies required for 5G and FR3. It is preferable that each comb-tooth electrode and the common electrode have a thickness of 0.1λ to 0.4λ and are embedded in the piezoelectric substrate to a depth of that thickness, but they may be embedded at a depth shallower than that thickness.

In addition, in the surface acoustic wave device according to the present invention, when the comb-tooth electrodes are arranged adjacent to each other, and when the wavelength of each comb-tooth electrode is λ, the interval between the center line of the electrode finger of the one comb-tooth electrode and the center line of the electrode finger of the other comb-tooth electrode that are adjacent may be (λ/2)×(an odd number of 3 or more). When the electrode finger of one comb-tooth electrode and the electrode finger of the other comb-tooth electrode are directly adjacent, for example, when a voltage V is applied between terminal A and terminal B, when the interval between the center lines of electrode fingers adjacent to each other is λ/2, the voltage between the adjacent electrode fingers becomes the same as the voltage V between the comb-tooth electrodes, and the electric field E between the electrode fingers becomes 2V/λ, so there is no significant merit in terms of withstand voltage. However, by setting the interval between the center lines of the adjacent electrode fingers to (λ/2)×(an odd number of 3 or more), although the voltage between the adjacent electrode fingers remains V, the electric field E becomes 2V/[λ×(an odd number of 3 or more)], and the electric field E can be reduced to ⅓, ⅕, . . . . For this reason, the withstand voltage can be increased, and it is possible to more effectively cope with high frequencies required for 5G and FR3.

Alternatively, in the surface acoustic wave device according to the present invention, the common electrode may also have a plurality of common electrode fingers arranged parallel to each electrode finger between the comb-tooth electrodes, and when the wavelength of the comb-tooth electrode is λ, among the common electrode fingers arranged between the comb-tooth electrodes, the interval between the center lines of two adjacent common electrode fingers may be (λ/2)×(an odd number of 3 or more). Also in this case, it is possible to more effectively cope with high frequencies required for 5G and FR3.

In addition, it is preferable that the surface acoustic wave device according to the present invention has a pair of reflectors provided on one surface of the piezoelectric substrate and arranged so as to sandwich each comb-tooth electrode from both sides along the propagation direction of surface acoustic waves.

A ladder filter according to the present invention is characterized by having a series part formed by connecting a plurality of surface acoustic wave devices according to the present invention in series with each comb-tooth electrode as a connection terminal, and a parallel part formed by connecting one or more surface acoustic wave devices according to the present invention in parallel to each surface acoustic wave device of the series part with each comb-tooth electrode as a connection terminal.

The ladder filter according to the present invention can appropriately use, as the plurality of surface acoustic wave devices according to the present invention, those that can be connected to the first electrode and the second electrode only from one side, left or right, with respect to the arrangement direction of the first electrode fingers, the second electrode fingers, and the common electrode fingers, and those that can be connected to the first electrode or the second electrode from both the left and right sides, respectively. As a result, the ladder filter according to the embodiment of the present invention can shorten the routing electrodes when connecting the surface acoustic wave devices, and can suppress increases in resistance and stray capacitance due to the routing electrodes.

### Effects of the Invention

According to the present invention, it is possible to provide a surface acoustic wave device and a ladder filter that can cope with high frequencies required for 5G and FR3, and can obtain excellent withstand voltage and a relatively high impedance value without increasing the size of the device itself.

### BRIEF DESCRIPTION OF THE DRAWINGS

FIG. 1 is a plan view for explaining the principle of the surface acoustic wave device according to the present invention.

FIG. 2 (a) is a plan view of a conventional surface acoustic wave device, (b) is a plan view showing a configuration in which two surface acoustic wave devices of (a) are connected in series in a direction perpendicular to the propagation direction of the surface acoustic wave, (c) is a plan view showing a configuration in which four surface acoustic wave devices of (a) are connected in series in a direction perpendicular to the propagation direction of the surface acoustic wave, and (d) is a modified structure of (b), which is a plan view showing a structure in which two surface acoustic wave devices of (a) are connected in series along the propagation direction of the surface acoustic wave.

FIG. 3 (a) is a plan view, (b) is a plan view showing a first modified example, (c) is a plan view showing a second modified example, (d) is a plan view showing a third modified example, and (e) is a plan view showing a fourth modified example, of the surface acoustic wave device according to the embodiment of the present invention when the comb-tooth electrode of the conventional surface acoustic wave device shown in FIG. 2(a) is divided into two and the number of electrode fingers of each comb-tooth electrode is ½.

FIG. 4 (a) is a plan view, (b) is a plan view showing a first modified example, (c) is a plan view showing a second modified example, and (d) is a plan view showing a third modified example, of the surface acoustic wave device according to the embodiment of the present invention when the comb-tooth electrode of the conventional surface acoustic wave device shown in FIG. 2(a) is divided into three and the number of electrode fingers of each comb-tooth electrode is ⅓.

FIG. 5 (a) is a plan view showing a modified example of FIG. 3(e) in which the interval between adjacent electrode fingers is widened when the electrode finger of one comb-tooth electrode and the electrode finger of the other comb-tooth electrode are adjacent in the surface acoustic wave device according to the embodiment of the present invention, and (b) is a plan view showing a modified example of FIG. 3(a) in which the interval between common electrode fingers between the comb-tooth electrodes is widened.

FIG. 6 (a) and (b) are plan views showing a T-type ladder filter and a π-type ladder filter, respectively, according to an embodiment of the present invention.

FIG. 7 is a graph showing the frequency characteristics of the surface acoustic wave devices shown in FIG. 3(a), 3(c), and 3(e) and the conventional surface acoustic wave devices shown in FIG. 2(a) to 2(c).

FIG. 8 (a) is a graph showing the frequency characteristics of a modified example in which comb-tooth electrodes made of Al are embedded in a piezoelectric substrate made of a 26°YX LiNbO₃ (LN) substrate, and (b) is a graph showing the frequency characteristics of a modified example in which comb-tooth electrodes made of Cu are embedded in a piezoelectric substrate made of a 36.5°YX LiTaO₃ (LT) substrate, of the surface acoustic wave device according to the embodiment of the present invention.

FIG. 9 is a graph showing the frequency characteristics of higher-order modes of modified examples in which the comb-tooth electrodes and the interdigital transducers (wavelength: 1.3 μm) are embedded in the piezoelectric substrate, of the surface acoustic wave devices shown in FIG. 3(a), 3(c), and 3(e), and the conventional surface acoustic wave devices shown in FIG. 2(a) and 2(c).

FIG. 10 is a graph showing the frequency characteristics of higher-order modes of a modified example in which the wavelength of the comb-tooth electrodes made of Al is set to 0.6 μm, among the modified examples shown in FIG. 9, of the surface acoustic wave device shown in FIG. 3(a).

FIG. 11 (a) shows a configuration, (b) shows symbols, (c) shows an equivalent circuit, and (d) is a graph showing frequency characteristics of a conventional SAW (surface acoustic wave) resonator.

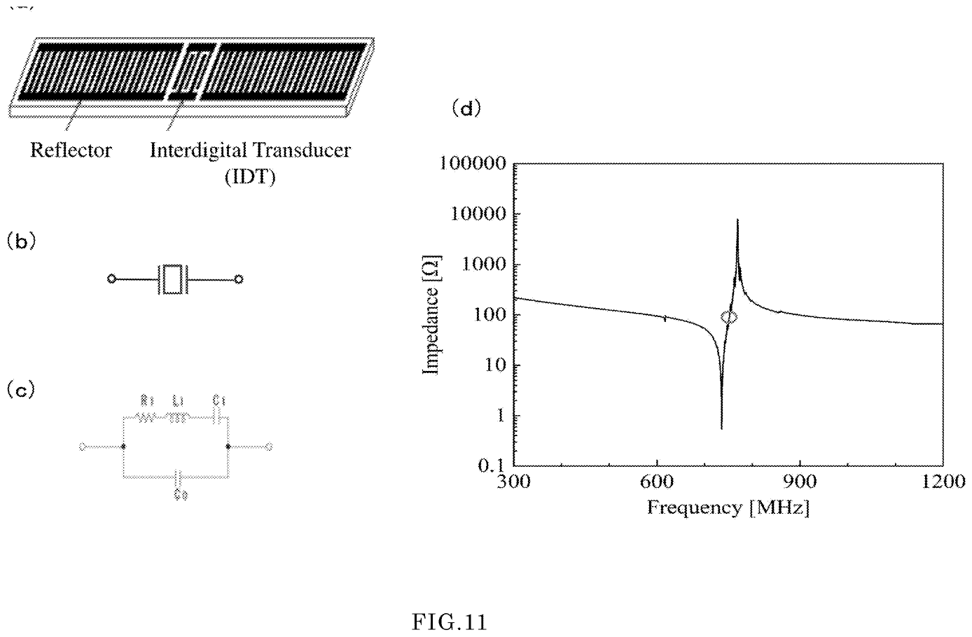

FIG. 12 (a) and (b) are perspective views showing a transversely coupled multimode resonator filter and a longitudinally coupled multimode resonator filter among filters utilizing the characteristics of conventional SAW resonators, respectively, and (c) and (d) are circuit diagrams showing a T-type ladder filter and a π-type ladder filter, respectively.

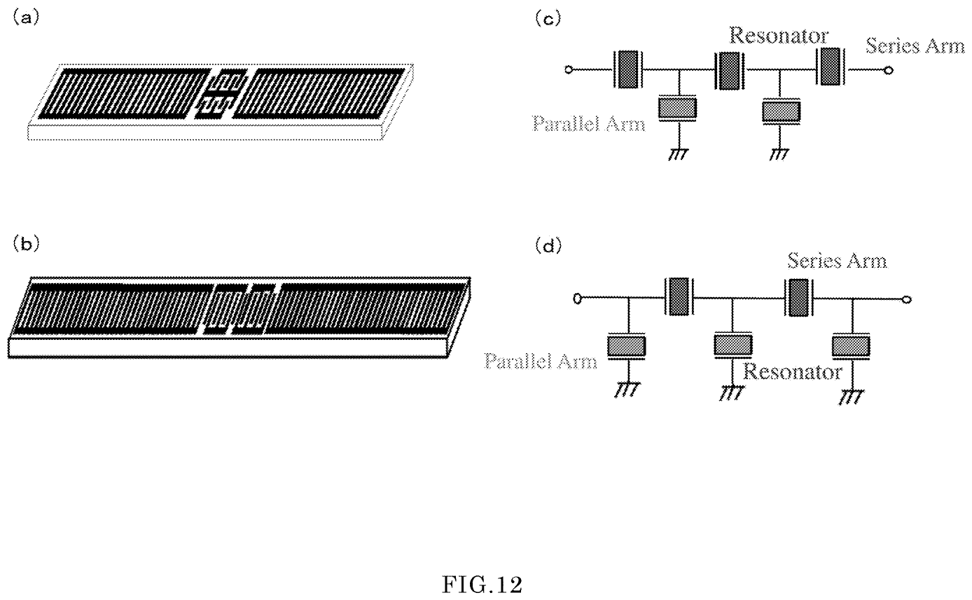

FIG. 13 is a graph showing the impedance characteristics when C₀ is 4 pF, 2 pF, 1 pF, 0.5 pF, and 0.25 pF, respectively, in the equivalent circuit shown in FIG. 11(c).

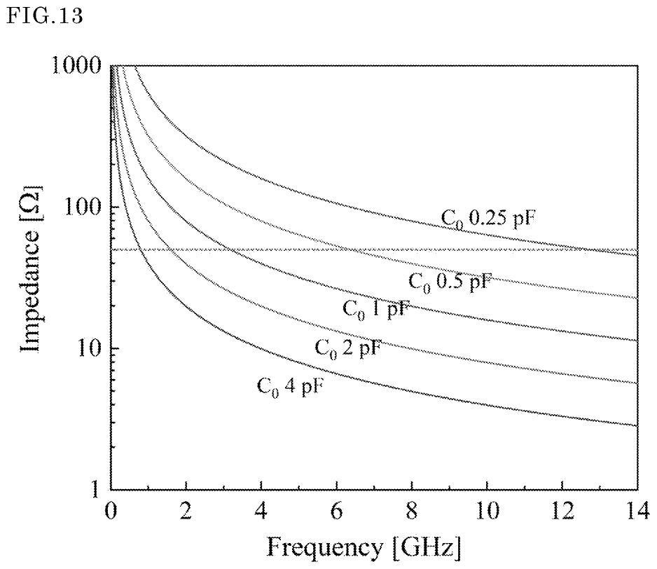

### DETAILED DESCRIPTION OF THE INVENTION

Hereinafter, an embodiment of the present invention will be described based on the drawings and examples.

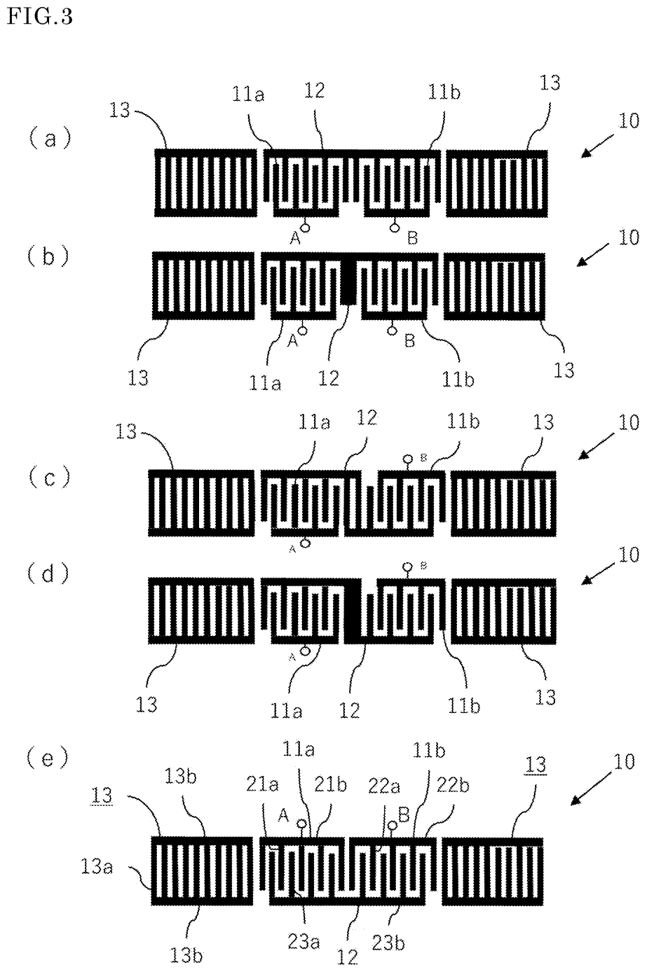

FIGS. 3 to 10 show a surface acoustic wave device according to an embodiment of the present invention.

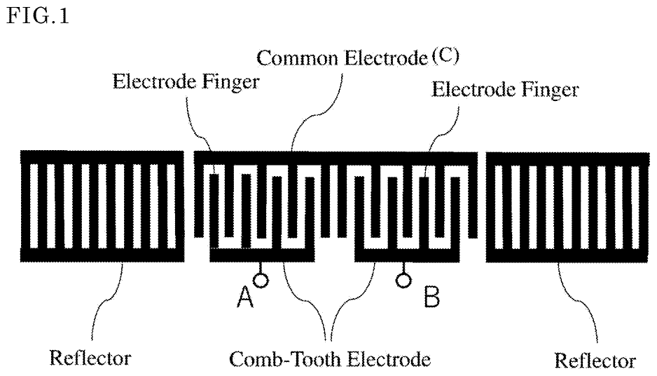

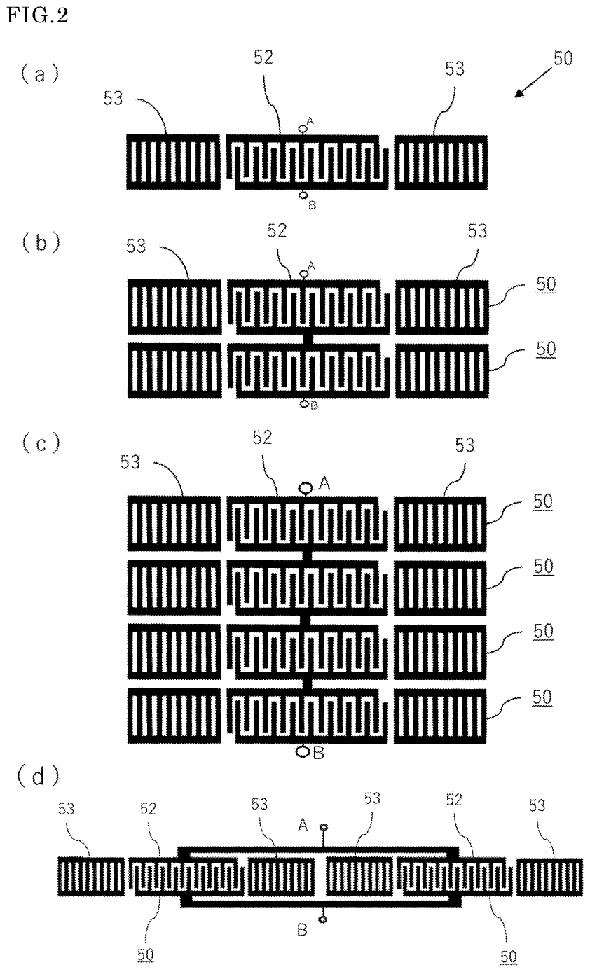

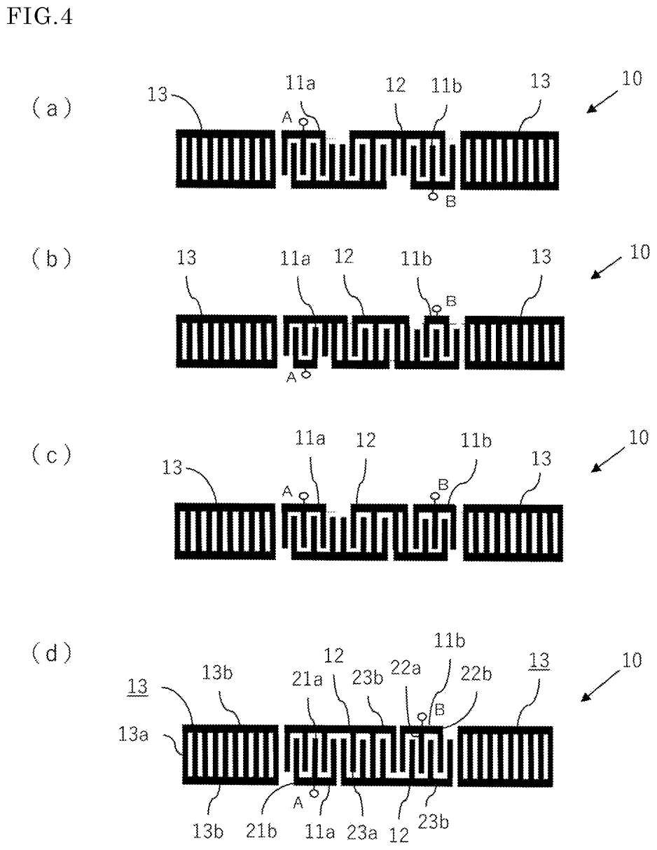

As shown in FIG. 3(a) to 3(e) and FIG. 4(a) to 4(d), the surface acoustic wave device 10 has a piezoelectric substrate (not shown), a pair of comb-tooth electrodes 11a, 11b, a common electrode 12, and a pair of grating reflectors 13. The surface acoustic wave device 10 shown in FIG. 3(a) has the same configuration as that in FIG. 1. FIG. 3(a) to 3(e) show those in which the comb-tooth electrode of the conventional surface acoustic wave device shown in FIG. 2(a) is divided into two, and FIG. 4(a) to 4(d) show those in which the comb-tooth electrode of the conventional surface acoustic wave device shown in FIG. 2(a) is divided into three.

In the surface acoustic wave device 10, the piezoelectric substrate is made of a single crystal of LiNbO₃ or LiTaO₃. The piezoelectric substrate has, for example, a thickness of 100 μm to 500 μm. The piezoelectric substrate is not limited to these, and may be made of a single crystal or thin film of Li₂B₄O₇, quartz, langasite, ZnO, ScAlN, or the like.

As shown in FIG. 3(a) to 3(e) and FIG. 4(a) to 4(d), each comb-tooth electrode 11a, 11b and the common electrode 12 are provided on one surface of the piezoelectric substrate. One comb-tooth electrode 11a has a plurality of electrode fingers 21a arranged parallel to each other at predetermined intervals, and a bus bar 21b provided to electrically connect one end or the other end of each electrode finger 21a. The other comb-tooth electrode 11b has the same number of electrode fingers 22a as the electrode fingers 21a, arranged parallel to each other at the same intervals as the electrode fingers 21a of the comb-tooth electrode 11a, and a bus bar 22b provided to electrically connect one end or the other end of each electrode finger 22a. Each comb-tooth electrode 11a, 11b is arranged at intervals from each other such that the electrode fingers 21a and the electrode fingers 22a are parallel to each other and the electrode fingers 21a and the electrode fingers 22a do not interdigitate with each other.

Each comb-tooth electrode 11a, 11b is connected to terminal A and terminal B, respectively. The terminals A and B of each comb-tooth electrode 11a, 11b may be provided at ends on the same side of the electrode fingers 22a, 22b, as shown in FIG. 3(a), 3(b), and 3(e) and FIG. 4(c), or may be provided at ends on opposite sides of the electrode fingers 22a, 22b, as shown in FIG. 3(c) and 3(d) and FIG. 4(a), 4(b), and 4(d).

The common electrode 12 has a plurality of common electrode fingers 23a arranged parallel to and at intervals from adjacent electrode fingers 21a and electrode fingers 22a so as to face the electrode fingers 21a, 22a, between the electrode fingers 21a and between the electrode fingers 22a, and a common bus bar 23b provided to electrically connect each common electrode finger 23a. Each common electrode finger 23a may be arranged only between the electrode fingers 21a and between the electrode fingers 22a as shown in FIG. 3(e), may also be arranged between the comb-tooth electrodes 11a and 11b as shown in FIG. 3(a) to 3(d) and FIG. 4(a) to 4(d), and may also be arranged outside the electrode fingers 21a on the side of the comb-tooth electrode 11a opposite to the comb-tooth electrode 11b and/or outside the electrode fingers 22a on the side of the comb-tooth electrode 11b opposite to the comb-tooth electrode 11a, as shown in FIG. 3(a) to 3(d) and FIG. 4(b) and 4(d). In addition, as shown in FIG. 4(a) to 4(d), among the plurality of common electrode fingers 23a arranged between the comb-tooth electrodes 11a and 11b, some common electrode fingers 23a may be arranged so as to interdigitate with each other, forming a third resonator. All the common electrode fingers 23a are arranged parallel to the electrode fingers 21a and the electrode fingers 22a.

The common bus bar 23b electrically connects all the common electrode fingers 23a, but is not electrically connected to the electrode fingers 21a and the electrode fingers 22a. The common bus bar 23b may be provided only on one end side or the other end side with respect to each common electrode finger 23a, as shown in FIG. 3(a), 3(b), and 3(e), or may be provided on one end side and the other end side, as shown in FIG. 3(c) and 3(d) and FIG. 4(a) to 4(d).

Each comb-tooth electrode 11a, 11b is configured such that, where λ is the wavelength, the interval between the center lines of adjacent electrode fingers among the electrode fingers 21a, the electrode fingers 22a, and the common electrode fingers 23a arranged parallel to each other is λ/2. In addition, each comb-tooth electrode 11a, 11b is electrically coupled via the common electrode 12, and is configured so that an electrical signal is applied between the terminals A and B to excite a SAW and obtain resonator characteristics.

The pair of grating reflectors 13 are provided on one surface of the piezoelectric substrate, and each has a plurality of reflector electrode fingers 13a arranged parallel at predetermined intervals, and a pair of reflector bus bars 13b that electrically connect both ends of each reflector electrode finger 13a. Each grating reflector 13 has a ladder shape and is made of the same material as each comb-tooth electrode 11a, 11b. Each grating reflector 13 is arranged so as to sandwich each comb-tooth electrode 11a, 11b from both sides along the propagation direction of the SAW.

Next, the operation will be described based on specific examples shown in FIGS. 3 and 4.

In the surface acoustic wave device 10 shown in FIG. 3(a) to 3(e), the number of electrode fingers 21a of the comb-tooth electrode 11a and the number of electrode fingers 22a of the comb-tooth electrode 11b are approximately ½ of the number of pairs of the interdigital transducer 52 of the conventional surface acoustic wave device 50 shown in FIG. 2(a). In addition, in the surface acoustic wave device 10 shown in FIG. 4(a) to 4(d), the number of electrode fingers 21a of the comb-tooth electrode 11a and the number of electrode fingers 22a of the comb-tooth electrode 11b are approximately ⅓ of the number of pairs of the interdigital transducer 52 of the conventional surface acoustic wave device 50 shown in FIG. 2(a). In addition, three resonators are connected in series: two resonators in which the electrode fingers 21a of the comb-tooth electrode 11a and the electrode fingers 22a of the comb-tooth electrode 11b interdigitate with the common electrode fingers 23a of the common electrode 12, respectively, and one resonator in which the common electrode fingers 23a of the common electrode interdigitate with each other. In addition, the surface acoustic wave device 10 shown in FIGS. 3 and 4 is configured such that the total of the electrode fingers 21a, the electrode fingers 22a, and the common electrode fingers 23a is approximately the same number as the number of electrode fingers of the interdigital transducer 52 of the conventional surface acoustic wave device 50 shown in FIG. 2(a).

In the surface acoustic wave device 10 shown in FIG. 3(a) to 3(e), since the number of electrode fingers 21a of the comb-tooth electrode 11a is approximately ½ of the number of pairs of the interdigital transducer 52 of the surface acoustic wave device 50 shown in FIG. 2(a) and two resonators are connected in series, the capacitance of the comb-tooth electrode 11a becomes approximately ½ of the capacitance of the interdigital transducer 52 of the surface acoustic wave device 50 shown in FIG. 2(a). Similarly, the capacitance of the comb-tooth electrode 11b also becomes ½ of the capacitance of the interdigital transducer 52 of the surface acoustic wave device 50 shown in FIG. 2(a). Furthermore, since each comb-tooth electrode 11a, 11b is coupled in series via the common electrode 12, the overall capacitance becomes ¼ of the capacitance of the interdigital transducer 52 of the surface acoustic wave device 50 shown in FIG. 2(a). For this reason, the impedance value of the surface acoustic wave device 10 shown in FIG. 3 becomes four times the impedance value of the interdigital transducer 52 of the surface acoustic wave device 50 shown in FIG. 2(a). This is the same as that shown in FIG. 2(c) in which four surface acoustic wave devices 50 of FIG. 2(a) are connected in series, and the size of the device itself becomes ¼.

In addition, when the same voltage is applied between terminal A and terminal B, in the surface acoustic wave device 10 shown in FIG. 3(a) to 3(e), the voltage between the comb-tooth electrode 11a and the common electrode 12, and between the comb-tooth electrode 11b and the common electrode 12, is ½ of the voltage between adjacent electrode fingers of the interdigital transducer 52 of the surface acoustic wave device 50 shown in FIG. 2(a) (the voltage between terminal A and terminal B). In addition, in the surface acoustic wave device 10 shown in FIG. 3(e), since the comb-tooth electrode 11a and the comb-tooth electrode 11b are adjacent to each other, the voltage between the adjacent electrode finger 21a and electrode finger 22a is the same as the voltage between terminal A and terminal B, but in the surface acoustic wave device 10 shown in FIG. 3(a) to 3(d), since a plurality of common electrode fingers 23a are arranged between the comb-tooth electrode 11a and the comb-tooth electrode 11b, the voltage between each electrode finger is ½ of the voltage between terminal A and terminal B or zero. FIG. 3(b) and 3(d) are modifications in which the two common electrode fingers 23a between the comb-tooth electrode 11a and the comb-tooth electrode 11b in FIG. 3(a) and 3(c), respectively, are formed as one thick electrode finger, and the thicker electrode finger can reduce defects such as wire breakage.

Similarly, in the surface acoustic wave device 10 shown in FIG. 4(a) to 4(d), since the number of electrode fingers 21a of the comb-tooth electrode 11a is approximately ⅓ of the number of pairs of the interdigital transducer 52 of the surface acoustic wave device 50 shown in FIG. 2(a) and three resonators are connected in series, the capacitance of the comb-tooth electrode 11a becomes approximately ⅓ of the capacitance of the interdigital transducer 52 of the surface acoustic wave device 50 shown in FIG. 2(a). Similarly, the capacitance of the comb-tooth electrode 11b also becomes ⅓ of the capacitance of the interdigital transducer 52 of the surface acoustic wave device 50 shown in FIG. 2(a). For this reason, the overall capacitance and impedance value of the surface acoustic wave device 10 shown in FIG. 4 become 1/9 of the capacitance and nine times the impedance value, respectively, of the interdigital transducer 52 of the surface acoustic wave device 50 shown in FIG. 2(a). This is the same as connecting nine surface acoustic wave devices 10 of FIG. 2(a) in series, and the size of the device itself becomes 1/9.

In addition, when the same voltage is applied between terminal A and terminal B, in the surface acoustic wave device 10 shown in FIG. 4(d), by the arrangement of the common electrode fingers 23a, the voltage between the comb-tooth electrode 11a and the common electrode 12, and between the comb-tooth electrode 11b and the common electrode 12, can be made ⅔ of the voltage between adjacent electrode fingers of the interdigital transducer 52 of the surface acoustic wave device 50 shown in FIG. 2(a) (the voltage between terminal A and terminal B). In the surface acoustic wave device 10 shown in FIG. 4(a) to 4(c), by the arrangement of the common electrode fingers 23a, the voltage between the comb-tooth electrode 11a and the common electrode 12, and between the comb-tooth electrode 11b and the common electrode 12, can be made ⅓ of the voltage between adjacent electrode fingers of the interdigital transducer 52 of the surface acoustic wave device 50 shown in FIG. 2(a) (the voltage between terminal A and terminal B).

Thus, the surface acoustic wave device 10 can reduce the capacitance and obtain a relatively high impedance value compared to the conventional surface acoustic wave device 50 of the same size. For this reason, the size can be significantly reduced compared to the case of connecting a plurality of conventional surface acoustic wave devices 50 in series. In addition, it is not necessary to connect a plurality of conventional surface acoustic wave devices 50 in series, and routing electrodes for that purpose are also unnecessary, so the stray capacitance due to the routing electrodes can be reduced. In addition, since the voltage between each electrode finger can be reduced compared to the conventional surface acoustic wave device 50, it is also excellent in withstand voltage.

Thus, the surface acoustic wave device 10 can obtain excellent withstand voltage and a relatively high impedance value without increasing the size of the device itself. In addition, since high impedance value and small capacitance can be achieved, it can easily cope with high frequencies required for 5G and FR3.

In the surface acoustic wave device 10, each comb-tooth electrode 11a and the common electrode 12 may be embedded in one surface of the piezoelectric substrate. In this case, for example, high-frequency harmonics of 4 GHz or higher can be effectively excited, and it is possible to easily cope with high frequencies required for 5G and FR3. It is preferable that each comb-tooth electrode 11a and the common electrode 12 have a thickness of 0.1λ to 0.4λ and are embedded in the piezoelectric substrate to a depth of that thickness, but they may be embedded at a depth shallower than that thickness.

In addition, when each comb-tooth electrode 11a, 11b is embedded, in order to effectively excite high-frequency harmonics, the metallization ratio MR of each comb-tooth electrode 11a, 11b is preferably MR=0.25 to 0.8. In addition, the embedding depth of each comb-tooth electrode 11a, 11b is preferably 0.15 to 0.5 wavelengths for each comb-tooth electrode 11a, 11b having a density of 2.5 to 7×10³ kg/m³, such as Al or Ti, preferably 0.05 to 0.4 wavelengths for each comb-tooth electrode 11a, 11b having a density of 7 to 11×10³ kg/m³, such as Cu, Mo, Ni, or Ag, and preferably 0.03 to 0.35 wavelengths for each comb-tooth electrode 11a, 11b having a density of 11 to 23×10³ kg/m³, such as Au, W, Ta, or Pt. The metallization ratio is the ratio obtained by dividing the width F of each electrode finger of each comb-tooth electrode 11a, 11b by half the period of the electrode fingers (wavelength λ) (the sum of the width F of the electrode finger and the gap G between electrode fingers), and MR=F/(F+G)=2×F/λ.

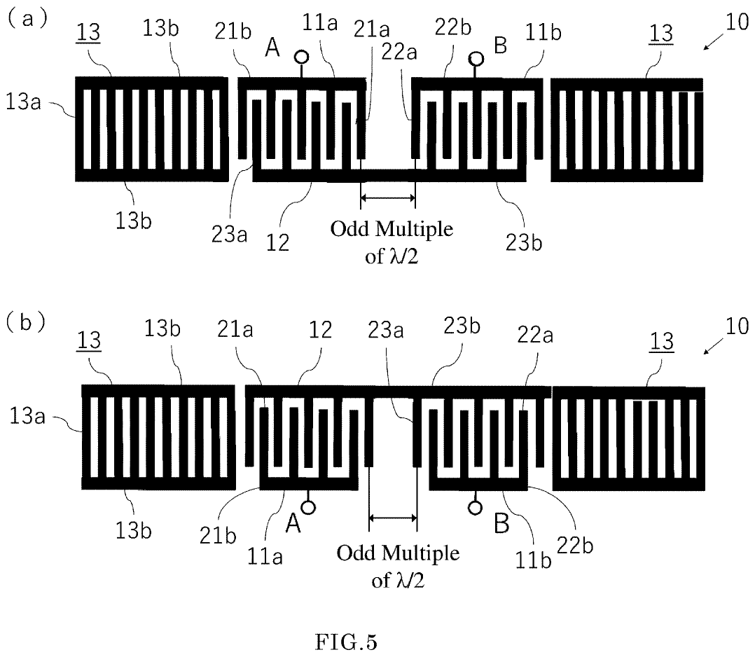

In addition, as shown in FIG. 5(a), in the surface acoustic wave device 10 shown in FIG. 3(e) in which the electrode finger 21a and the electrode finger 22a are adjacent, the interval between the center line of the adjacent electrode finger 21a and the center line of the electrode finger 22a may be (λ/2)×(an odd number of 3 or more). In this case, for example, when a voltage V is applied between terminal A and terminal B, the voltage between the adjacent electrode fingers is the same as the voltage V between the comb-tooth electrodes, but compared to when the interval between the center lines of the adjacent electrode fingers is λ/2, the electric field E between the adjacent electrode fingers can be made ⅓, ⅕, . . . . For this reason, the withstand voltage can be increased, and it is possible to more effectively cope with high frequencies required for 5G and FR3. In addition, as shown in FIG. 5(b), in the surface acoustic wave device 10 shown in FIG. 3(a) and 3(c) in which a plurality of common electrode fingers 23a are arranged between the comb-tooth electrode 11a and the comb-tooth electrode 11b, the interval between the center lines of two adjacent common electrode fingers 23a between the comb-tooth electrode 11a and the comb-tooth electrode 11b may be (λ/2)×(an odd number of 3 or more). Also in these cases, it is possible to more effectively cope with high frequencies required for 5G and FR3.

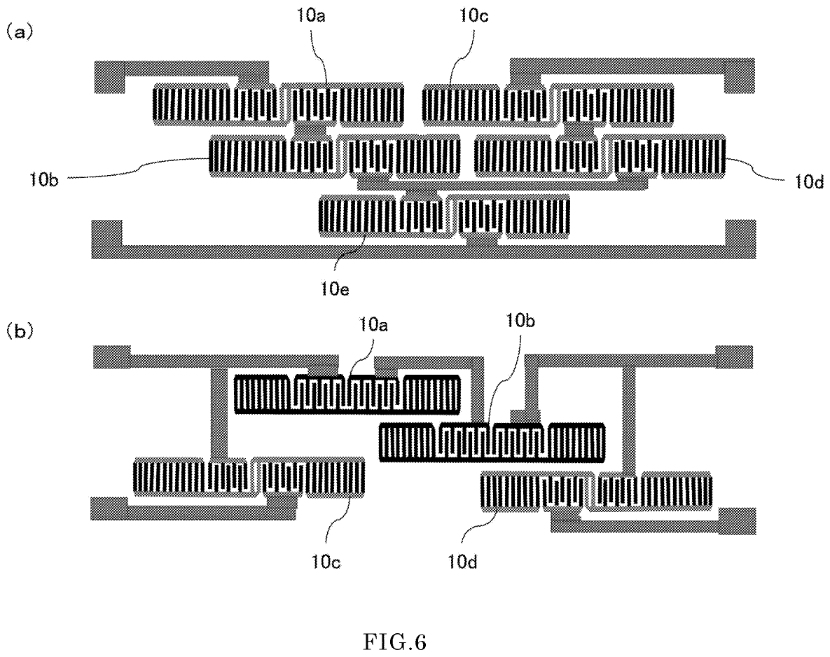

As shown in FIG. 6, the ladder filter 30 according to the embodiment of the present invention has a series part formed by connecting a plurality of surface acoustic wave devices 10 in series, and a parallel part formed by connecting one or more surface acoustic wave devices 10 in parallel to each surface acoustic wave device 10 of the series part. Each surface acoustic wave device 10 is connected with the comb-tooth electrode 11a and the comb-tooth electrode 11b as connection terminals.

In a specific example shown in FIG. 6(a), it is composed of a T-type ladder filter and has five surface acoustic wave resonators 10a to 10e, in which the comb-tooth electrode 11b of the first surface acoustic wave resonators 10a and the comb-tooth electrode 11a of the second surface acoustic wave resonator 10b are connected, the comb-tooth electrode 11b of the third surface acoustic wave resonator 10c and the comb-tooth electrode 11a of the fourth surface acoustic wave resonator 10d are connected, and the comb-tooth electrode 11b of the second surface acoustic wave resonator 10b and the comb-tooth electrode 11b of the fourth surface acoustic wave resonator 10d and the comb-tooth electrode 11a of the fifth surface acoustic wave resonator 10e are connected. In this case, when the first, second, and fifth surface acoustic wave resonators 10a, 10b, 10e are the series part, the third and fourth surface acoustic wave resonators 10c, 10d form the parallel part, and when the third, fourth, and fifth surface acoustic wave resonators 10c, 10d, 10e are the series part, the first and second surface acoustic wave resonators 10a, 10b form the parallel part.

In addition, in a specific example shown in FIG. 6(b), it is composed of a π-type ladder filter and has four surface acoustic wave resonators 10a to 10d, in which the comb-tooth electrode 11b of the first surface acoustic wave resonator 10a and the comb-tooth electrode 11a of the second surface acoustic wave resonator 10b are connected, the comb-tooth electrode 11a of the first surface acoustic wave resonator 10a and the comb-tooth electrode 11a of the third surface acoustic wave resonator 10c are connected, and the comb-tooth electrode 11b of the second surface acoustic wave resonator 10b and the comb-tooth electrode 11b of the fourth surface acoustic wave resonator 10d are connected. In this case, the first and second surface acoustic wave resonators 10a, 10b form the series part, and the third and fourth surface acoustic wave resonators 10c, 10d form the parallel part.

The ladder filter 30 can arrange the terminal A and the terminal B on one side, left or right, with respect to the arrangement direction of the electrode fingers 21a, the electrode fingers 22a, and the common electrode fingers 23a of the surface acoustic wave device 10, as shown in FIG. 3(a), 3(b), and 3(e) and FIG. 4(c), and can arrange the terminal A on one side, left or right, and the terminal B on the other side, as shown in FIG. 3(c) and 3(d) and FIG. 4(a), 4(b), and 4(d). For this reason, by appropriately using these surface acoustic wave devices 10, it is possible to connect to the comb-tooth electrode 11a and the comb-tooth electrode 11b of each surface acoustic wave device 10 from a desired direction. As a result, whereas when using the conventional surface acoustic wave device 50 shown in FIG. 2(a), connection could only be made from the left and right opposite sides with respect to the arrangement direction of each electrode finger, the ladder filter 30 can shorten the routing electrodes and can suppress increases in resistance and stray capacitance due to the routing electrodes.

### EXAMPLE 1

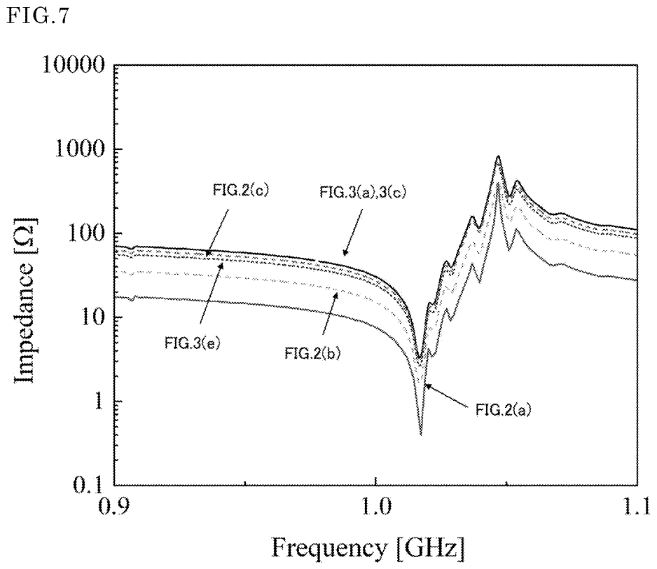

The frequency characteristics of the surface acoustic wave device 10 shown in FIG. 3(a), 3(c), and 3(e), and the conventional surface acoustic wave device 50 shown in FIG. 2(a) to 2(c), were obtained and are shown in FIG. 7. Here, each comb-tooth electrode 11a, 11b, the common electrode 12, and the interdigital transducer 52 were made of Cu, their thickness was set to 0.06λ (λ is the wavelength of each comb-tooth electrode 11a, 11b), and the electrodes were formed on a 42°YX LiTaO₃ (LT) substrate. As shown in FIG. 7, it was confirmed that for the surface acoustic wave device 50 shown in FIG. 2(a), the impedance value (Impedance) of that shown in FIG. 2(b), in which two surface acoustic wave devices 50 shown in FIG. 2(a) were connected in series, became approximately twice, and the impedance value of that shown in FIG. 2(c), in which four surface acoustic wave devices 50 shown in FIG. 2(a) were connected in series, became approximately four times. In addition, it was confirmed that the surface acoustic wave device 10 shown in FIG. 3(a), 3(c), and 3(e) had an impedance value approximately four times that of the conventional surface acoustic wave device 50 shown in FIG. 2(a), despite having the same size.

When the impedance ratio (=20×log(antiresonance impedance/resonance impedance)) was obtained, it was 60 dB for the surface acoustic wave device 50 shown in FIG. 2(a), whereas it was 55 dB for that shown in FIG. 2(b), and 50 to 53 dB for that shown in FIG. 2(c) and the surface acoustic wave device 10 shown in FIG. 3(a), 3(c), and 3(e), and it was confirmed that the impedance became slightly smaller. It was also confirmed that the frequency characteristics of the surface acoustic wave device 10 shown in FIG. 3(a), 3(c), and 3(e) shown in FIG. 7 did not change significantly when the number of pairs of electrode fingers formed by the electrode fingers 21a, the electrode fingers 22a, and the common electrode fingers 23a was in the range of 0.7 N/M to 1.3 N/M (where N is the total number of pairs of electrode fingers and M is the number of divisions or the number of resonators connected in series).

### EXAMPLE 2

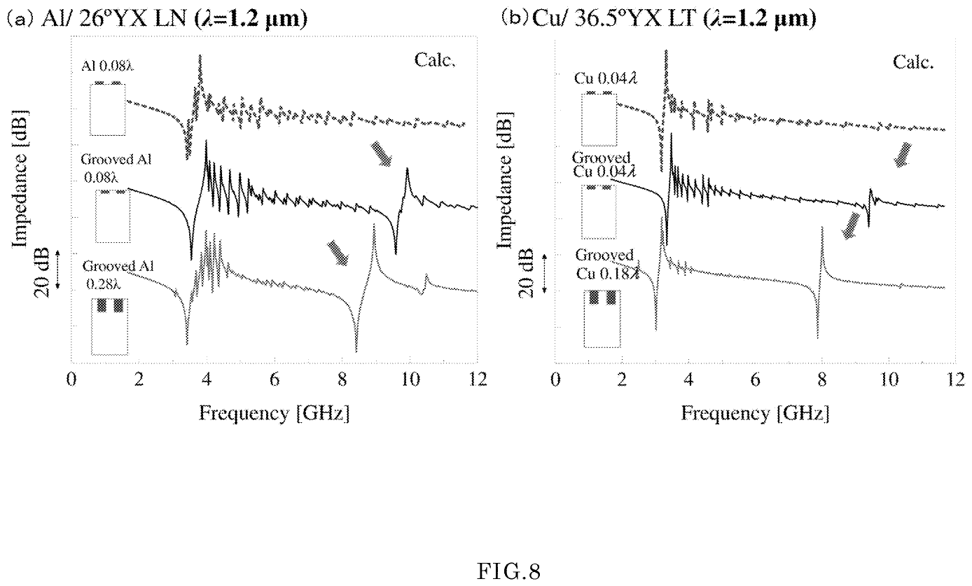

For the surface acoustic wave device 10 shown in FIG. 3(e), the frequency characteristics when each comb-tooth electrode 11a, 11b and the common electrode 12 were embedded in the piezoelectric substrate were obtained and are shown in FIG. 8. First, in FIG. 8(a), each comb-tooth electrode 11a, 11b is made of Al, and the piezoelectric substrate is a 26°YX LiNbO₃ (LN) substrate. FIG. 8(a) shows the frequency characteristics when each comb-tooth electrode 11a, 11b has a wavelength of 1.2 μm, a metallization ratio (MR)=0.5, and a thickness of 0.08 wavelengths, and the comb-tooth electrodes 11a, 11b were formed on the surface of the piezoelectric substrate (indicated as “Al 0.08λ” in the figure), when the comb-tooth electrodes 11a, 11b with a wavelength of 1.2 μm and MR=0.5 were embedded at a depth of 0.08 wavelengths from the surface of the piezoelectric substrate (indicated as “Grooved Al 0.08λ” in the figure), and when the comb-tooth electrodes 11a, 11b with a wavelength of 1.2 μm and MR=0.5 were embedded at a depth of 0.28 wavelengths from the surface of the piezoelectric substrate (indicated as “Grooved Al 0.28λ” in the figure).

As shown in FIG. 8(a), when each comb-tooth electrode 11a, 11b was formed on the surface of the piezoelectric substrate, only the fundamental wave near 4 GHz was excited, and at higher frequencies, only small spurious responses were observed. In contrast, when each comb-tooth electrode 11a, 11b was embedded in the piezoelectric substrate, it was confirmed that in addition to the fundamental wave near 4 GHz, a high-velocity surface acoustic wave having a wavelength approximately 2.3 to 3 times that of the fundamental wave was excited near 8 GHz to near 10 GHz. In addition, it was confirmed that the impedance ratio of the high-velocity surface acoustic wave (harmonic SAW) was larger when the comb-tooth electrodes 11a, 11b were embedded at a depth of 0.28 wavelengths from the surface of the piezoelectric substrate than when the comb-tooth electrodes 11a, 11b were embedded at a depth of 0.08 wavelengths from the surface of the piezoelectric substrate.

Next, in FIG. 8(b), each comb-tooth electrode 11a, 11b was made of Cu, and the piezoelectric substrate is a 36.5°YX LiTaO₃ (LT) substrate. FIG. 8(b) shows the frequency characteristics when each comb-tooth electrode 11a, 11b had a wavelength of 1.2 μm, MR=0.5, and a thickness of 0.04 wavelengths, and the comb-tooth electrodes 11a, 11b were formed on the surface of the piezoelectric substrate (indicated as “Cu 0.04λ” in the figure), when the comb-tooth electrodes 11a, 11b with a wavelength of 1.2 μm and MR=0.5 were embedded at a depth of 0.04 wavelengths from the surface of the piezoelectric substrate (indicated as “Grooved Cu 0.04λ” in the figure), and when the comb-tooth electrodes 11a, 11b with a wavelength of 1.2 μm and MR=0.5 were embedded at a depth of 0.18 wavelengths from the surface of the piezoelectric substrate (indicated as “Grooved Cl 0.18λ” in the figure).

As shown in FIG. 8(b), when each comb-tooth electrode 11a, 11b was formed on the surface of the piezoelectric substrate, only the fundamental wave near 3 to 4 GHz was excited, and at higher frequencies, only small spurious responses were observed. In contrast, when each comb-tooth electrode 11a, 11b was embedded in the piezoelectric substrate, it was confirmed that in addition to the fundamental wave near 3 to 4 GHz, a high-velocity surface acoustic wave having a wavelength approximately 2.3 to 3 times that of the fundamental wave was excited near 8 GHz to near 10 GHz. In addition, it was confirmed that the impedance ratio of the high-velocity surface acoustic wave was larger when the comb-tooth electrodes 11a, 11b were embedded at a depth of 0.18 wavelengths from the surface of the piezoelectric substrate than when the comb-tooth electrodes 11a, 11b were embedded at a depth of 0.04 wavelengths from the surface of the piezoelectric substrate. When the comb-tooth electrodes 11a, 11b are made of Cu, since they have a higher density than those made of Al, a large impedance ratio can be obtained even if the embedding depth of the comb-tooth electrodes 11a, 11b is shallower than those made of Al.

### EXAMPLE 3

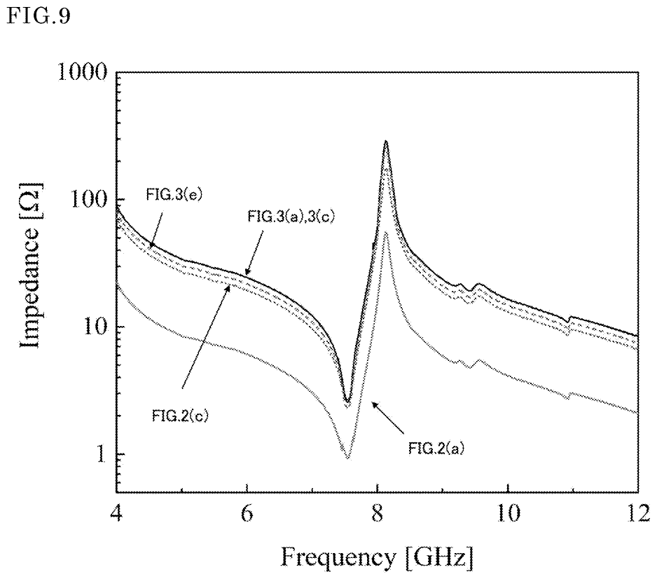

For the surface acoustic wave device 10 shown in FIG. 3(a), 3(c), and 3(e), and the conventional surface acoustic wave device 50 shown in FIG. 2(a) and 2(c), the frequency characteristics of higher-order modes when the comb-tooth electrodes 11a, 11b, the common electrode 12, and the interdigital transducer 52 were embedded in the piezoelectric substrate were obtained and are shown in FIG. 9. Here, each comb-tooth electrode 11a, 11b, the common electrode 12, and the interdigital transducer 52 were made of Al, their wavelength was 1.3 μm, and their thickness was 0.25 wavelengths, and the piezoelectric substrate was a 26°YX LiNbO₃ (LN) substrate. In addition, each comb-tooth electrode 11a, 11b, the common electrode 12, and the interdigital transducer 52 were embedded at a depth of 0.25 wavelengths from the surface of the piezoelectric substrate.

As shown in FIG. 9, it was confirmed that harmonics were excited near 8 GHz in all of the surface acoustic wave device 10 shown in FIG. 3(a), 3(c), and 3(e), and the conventional surface acoustic wave device 50 shown in FIG. 2(a) and 2(c). In addition, it was confirmed that four surface acoustic wave devices 50 shown in FIG. 2(a) connected in series shown in FIG. 2(c), had an impedance value approximately four times that of the surface acoustic wave device 10 shown in FIG. 2(a). In addition, it was confirmed that the surface acoustic wave device 10 shown in FIG. 3(a), 3(c), and 3(e) had an impedance value approximately four times that of the surface acoustic wave device 50 shown in FIG. 2(a), despite having the same size.

It was confirmed that the conventional surface acoustic wave device 50 shown in FIG. 2(a) had a center frequency impedance value lower than 50 ohms, so the peak at the resonance frequency was blunted, and the impedance ratio was also about 32 dB. In addition, it was confirmed that that shown in FIG. 2(c) had a center frequency impedance value close to 50 ohms, but the impedance ratio was about 37 dB. In addition, since that shown in FIG. 2(c) has a slightly smaller impedance value than the surface acoustic wave device 10 shown in FIG. 3(a), 3(c), and 3(e), it is considered to be affected by the stray capacitance of the routing electrodes and the like. In contrast, it was confirmed that the surface acoustic wave device 10 shown in FIG. 3(a) to 3(c) had a center frequency impedance value close to 50 ohms, and the impedance ratio was 41 dB, which is somewhat large.

In addition, it was confirmed that the same results as those of the surface acoustic wave device 10 shown in FIG. 3(a), 3(c), and 3(e) were also obtained for the surface acoustic wave device 10 shown in FIG. 4. The reason why the impedance ratio of the high-velocity mode shown in FIG. 9 is smaller than the impedance ratio of the resonance characteristics near 1 GHz shown in FIG. 7 is considered to be that the acoustic loss depending on frequency becomes larger at high frequencies.

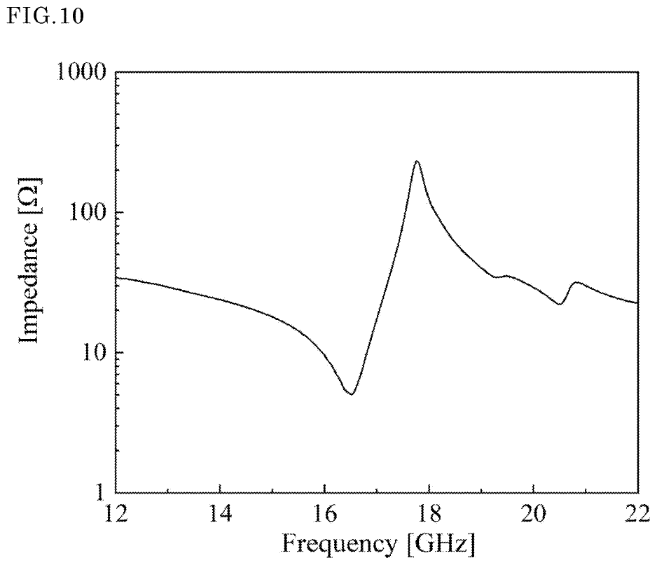

Next, for the surface acoustic wave device 10 shown in FIG. 3(a), the frequency characteristics of higher-order modes when the wavelength of the comb-tooth electrodes 11a, 11b made of Al was set to 0.6 μm and the other conditions were the same as those in FIG. 9 are shown in FIG. 10. As shown in FIG. 10, it was confirmed that by setting the wavelength of each comb-tooth electrode 11a, 11b to approximately half, harmonics were excited at a position approximately twice the frequency of the harmonics (near 8 GHz) shown in FIG. 9 (near 17 to 18 GHz). It was confirmed that this harmonic had a center frequency impedance value close to 50 ohms and an impedance ratio of 41 dB.

### REFERENCE SIGNS LIST

10 Surface acoustic wave device
11a, 11b Comb-tooth electrode
21a, 22a Electrode finger
21b, 22b Bus bar
12 Common electrode
23a Common electrode finger
23b Common bus bar
13 Grating reflector
30 Ladder filter
50 (Conventional) surface acoustic wave device
52 Interdigital transducer
53 Reflector

1. A surface acoustic wave device comprising:
a piezoelectric substrate;
a pair of comb-tooth electrodes which are arranged side by side along a propagation direction of surface acoustic waves on one surface of the piezoelectric substrate and are respectively connected to a pair of terminals for applying voltage; and
a common electrode which electrically couples each comb-tooth electrode,
wherein each comb-tooth electrode has a plurality of electrode fingers arranged parallel to each other at predetermined intervals along the propagation direction of surface acoustic waves,
the electrode fingers of one comb-tooth electrode and the electrode fingers of the other comb-tooth electrode are arranged at intervals from each other so as not to interdigitate with each other, and
the common electrode has a plurality of common electrode fingers arranged parallel to and at intervals from adjacent electrode fingers between electrode fingers of one comb-tooth electrode and between electrode fingers of the other comb-tooth electrode, and the common electrode fingers are electrically connected to each other.

2. The surface acoustic wave device according to claim 1, wherein the common electrode has one or more common electrode fingers arranged parallel to each electrode finger between the comb-tooth electrodes.

3. The surface acoustic wave device according to claim 1, wherein the common electrode also has common electrode fingers arranged parallel to each electrode finger on a side of the one comb-tooth electrode opposite to the other comb-tooth electrode and/or on a side of the other comb-tooth electrode opposite to the one comb-tooth electrode.

4. The surface acoustic wave device according to claim 1, wherein a plurality of the common electrodes are provided, and portions of the common electrode fingers of the respective common electrodes interdigitate with each other.

5. The surface acoustic wave device according to claim 1, wherein each comb-tooth electrode and the common electrode are embedded in one surface of the piezoelectric substrate.

6. The surface acoustic wave device according to claim 1, wherein harmonics of 4 GHz or higher are used as the surface acoustic waves.

7. The surface acoustic wave device according to claim 1, wherein the comb-tooth electrodes are arranged adjacent to each other, and when the wavelength of each comb-tooth electrode is λ, an interval between a center line of an electrode finger of the one comb-tooth electrode and a center line of an electrode finger of the other comb-tooth electrode that are adjacent is (λ/2)×(an odd number of 3 or more).

8. The surface acoustic wave device according to claim 1, wherein
the common electrode also has a plurality of common electrode fingers arranged parallel to each electrode finger between the comb-tooth electrodes, and
when the wavelength of each comb-tooth electrode is λ, among the common electrode fingers arranged between the comb-tooth electrodes, an interval between center lines of two adjacent common electrode fingers is (λ/2)×(an odd number of 3 or more).

9. The surface acoustic wave device according to claim 1, further comprising a pair of reflectors provided on one surface of the piezoelectric substrate and arranged so as to sandwich each comb-tooth electrode from both sides along the propagation direction of surface acoustic waves.

10. A ladder filter comprising:
a series part formed by connecting a plurality of surface acoustic wave devices according to claim 1 in series with each comb-tooth electrode as a connection terminal; and
a parallel part formed by connecting one or more surface acoustic wave devices in parallel to each surface acoustic wave device of the series part with each comb-tooth electrode as a connection terminal.

11. A ladder filter comprising:
a series part formed by connecting a plurality of surface acoustic wave devices according to claim 2 in series with each comb-tooth electrode as a connection terminal; and
a parallel part formed by connecting one or more surface acoustic wave devices in parallel to each surface acoustic wave device of the series part with each comb-tooth electrode as a connection terminal.

12. A ladder filter comprising:
a series part formed by connecting a plurality of surface acoustic wave devices according to claim 3 in series with each comb-tooth electrode as a connection terminal; and
a parallel part formed by connecting one or more surface acoustic wave devices in parallel to each surface acoustic wave device of the series part with each comb-tooth electrode as a connection terminal.

13. A ladder filter comprising:
a series part formed by connecting a plurality of surface acoustic wave devices according to claim 4 in series with each comb-tooth electrode as a connection terminal; and
a parallel part formed by connecting one or more surface acoustic wave devices in parallel to each surface acoustic wave device of the series part with each comb-tooth electrode as a connection terminal.

14. A ladder filter comprising:
a series part formed by connecting a plurality of surface acoustic wave devices according to claim 5 in series with each comb-tooth electrode as a connection terminal; and
a parallel part formed by connecting one or more surface acoustic wave devices in parallel to each surface acoustic wave device of the series part with each comb-tooth electrode as a connection terminal.

15. A ladder filter comprising:
a series part formed by connecting a plurality of surface acoustic wave devices according to claim 6 in series with each comb-tooth electrode as a connection terminal; and
a parallel part formed by connecting one or more surface acoustic wave devices in parallel to each surface acoustic wave device of the series part with each comb-tooth electrode as a connection terminal.

16. A ladder filter comprising:
a series part formed by connecting a plurality of surface acoustic wave devices according to claim 7 in series with each comb-tooth electrode as a connection terminal; and
a parallel part formed by connecting one or more surface acoustic wave devices in parallel to each surface acoustic wave device of the series part with each comb-tooth electrode as a connection terminal.

17. A ladder filter comprising:
a series part formed by connecting a plurality of surface acoustic wave devices according to claim 8 in series with each comb-tooth electrode as a connection terminal; and
a parallel part formed by connecting one or more surface acoustic wave devices in parallel to each surface acoustic wave device of the series part with each comb-tooth electrode as a connection terminal.

18. A ladder filter comprising:
a series part formed by connecting a plurality of surface acoustic wave devices according to claim 9 in series with each comb-tooth electrode as a connection terminal; and
a parallel part formed by connecting one or more surface acoustic wave devices in parallel to each surface acoustic wave device of the series part with each comb-tooth electrode as a connection terminal.
